(19) United States
(12) Patent Application Publication
(10) Pub. No.: US 2025/0126863 A1
(43) Pub. Date: Apr. 17, 2025

(54) SEMICONDUCTOR DEVICE AND METHOD FOR MANUFACTURING SEMICONDUCTOR DEVICE

(71) Applicant: FUJI ELECTRIC CO., LTD., Kanagawa (JP)

(72) Inventors: Hidenori TSUJI, Higashimurayama-city (JP); Shinya TAKASHIMA, Hachioji-city (JP); Katsunori UENO, Matsumoto-city (JP); Takashi YOSHIMURA, Matsumoto-city (JP); Shuntaro YAGUCHI, Matsumoto-city (JP)

(21) Appl. No.: 19/000,267

(22) Filed: Dec. 23, 2024

Related U.S. Application Data
(63) Continuation of application No. PCT/JP2023/043470, filed on Dec. 5, 2023.

(30) Foreign Application Priority Data
Dec. 8, 2022 (JP) 2022-196682

(51) Int. Cl. H10D 62/60; H01L 21/225; H10D 12/00; H10D 84/00

(52) U.S. Cl. CPC H10D 62/60; H01L 21/225; H10D 84/161; H10D 12/481

(57) ABSTRACT

Provided is a semiconductor device having a semiconductor substrate with the oxygen chemical concentration of 1×10¹⁶ atoms/cm³ or more, wherein it includes the bulk donor and an increased donor, includes a buffer region of a first conductivity type that has a doping concentration higher than that of the drift region, and has a concentration of the thermal donor that is 10% or less of a concentration of the increased donor at a same depth position throughout an entire first range from a lower end of the buffer region to the deepest peak.

The contents of the following patent application(s) are incorporated herein by reference:
NO. 2022-196682 filed in JP on Dec. 8, 2022
NO. PCT/JP2023/043470 filed in WO on Dec. 5, 2023

### BACKGROUND

### 1. Technical Field

The present invention relates to a semiconductor device and a manufacturing method of the semiconductor device.

### 2. Related Art

A technique to form a semiconductor device, such as a transistor, on a semiconductor substrate is known (for example, see Patent Document 1 and 2).

### PRIOR ART DOCUMENT

### Patent Document

Patent Document 1: Specification of U.S. Patent Application Publication No. 2020/0194550

Patent Document 2: Specification of U.S. Patent Application Publication No. 2016/0329401

### BRIEF DESCRIPTION OF THE DRAWINGS

FIG. 1 illustrates a top view showing an example of a semiconductor device 100 according to one embodiment of the present invention.

FIG. 2 illustrates an enlarged view of a region D in FIG. 1.

FIG. 3 illustrates an example of a cross section e-e in FIG. 2.

FIG. 4 illustrates a reference example of distribution 210 of doping concentrations on the line f-f of FIG. 3.

FIG. 5 illustrates distribution 210 of doping concentrations according to the example.

FIG. 6 illustrates an example of oxygen chemical concentration distribution and thermal donor concentration distribution in a region on the upper surface 21 side relative to the buffer region 20 (a region from a depth position Zb to a depth position Zu).

FIG. 7 is a flowchart describing an example of a manufacturing method of the semiconductor device 100.

FIG. 8 illustrates an exemplary temporal variation in the temperature of the semiconductor substrate 10 in each annealing step.

FIG. 9 is a flowchart showing a more specific example of the manufacturing method of the semiconductor device 100.

FIG. 10 is a flowchart showing processes following the processes of FIG. 9.

### DESCRIPTION OF EXEMPLARY EMBODIMENTS

Hereinafter, the invention will be described through embodiments of the invention, but the following embodiments do not limit the invention according to claims. In addition, not all of the combinations of features described in the embodiments are essential to the solution of the invention.

As used herein, one side in a direction parallel to a depth direction of a semiconductor substrate is referred to as “upper” and the other side is referred to as “lower”. One surface of two principal surfaces of a substrate, a layer or other member is referred to as an upper surface, and the other surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. Note that a +Z axis direction and a −Z axis direction are directions opposite to each other. When the Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. Further, an axis perpendicular to the upper surface and the lower surface of the semiconductor substrate is referred to as the Z axis. In the present specification, the direction of the Z axis may be referred to as the depth direction. Further, in the present specification, a direction parallel to the upper surface and the lower surface of the semiconductor substrate may be referred to as a horizontal direction, including an X axis direction and a Y axis direction.

A region from the center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}-N_{A}. NA. In the present specification, the net doping concentration may be simply referred to as the doping concentration.

The donor has a function of supplying electrons to a semiconductor. The acceptor has a function of receiving electrons from the semiconductor. The donor and the acceptor are not limited to the impurities themselves. For example, a VOH defect which is a combination of a vacancy (V), oxygen (O), and hydrogen (H) existing in the semiconductor functions as the donor that supplies electrons. The hydrogen donor may be a donor obtained by the combination of at least a vacancy (V) and hydrogen (H). Alternatively, interstitial Si-H in which interstitial silicon (Si-i) in a silicon semiconductor is attached to hydrogen, and CiOi-H in which interstitial carbon (Ci) is attached to interstitial oxygen (Oi) and hydrogen also function as a donor which supplies electrons. In the present specification, the VOH defect, the CiOi-H, or the interstitial Si—H may be referred to as the hydrogen donor.

In the semiconductor substrate of the present specification, bulk donors of the N type are distributed throughout. The bulk donor is a dopant donor substantially uniformly contained in an ingot during the manufacture of the ingot from which the semiconductor substrate is made. The bulk donor of this example is an element other than hydrogen. The bulk donor dopant is, for example, phosphorous, antimony, arsenic, selenium, or sulfur, but the invention is not limited to these. The bulk donor of this example is phosphorous. The bulk donor is also contained in a P type region. The semiconductor substrate may be a wafer cut out from a semiconductor ingot, or may be a chip obtained by singulating the wafer. The semiconductor ingot may be manufactured by either a Czochralski method (CZ method), a magnetic field applied Czochralski method (MCZ method), or a float zone method (FZ method). The ingot in this example is manufactured by the MCZ method. An oxygen concentration contained in the substrate manufactured by the MCZ method is 1×10¹⁷ to 7×10¹⁷/cm³. The oxygen concentration contained in the substrate manufactured by the FZ method is 1×10¹⁵ to 5×10¹⁶/cm³. When the oxygen concentration is high, hydrogen donors tend to be easily generated. The bulk donor concentration may use a chemical concentration of bulk donors distributed throughout the semiconductor substrate, or may be a value between 90% and 100% of the chemical concentration. Further, as the semiconductor substrate, a non-doped substrate not containing a dopant such as phosphorous may be used. In that case, the bulk donor concentration (D0) of the non-doped substrate is, for example, from 1×10¹⁰/cm³ or more and to 5×10¹²/cm³ or less. The bulk donor concentration (D0) of the non-doped substrate is preferably 1×10¹¹/cm³ or more. The bulk donor concentration (DO) of the non-doped substrate is preferably 5×10¹²/cm³ or less. Each concentration in the present invention may be a value at room temperature. As an example, a value at 300K (Kelvin) (about 26.9 degrees C.) may be used as the value at room temperature.

In the present specification, a description of a P+ type or an N+ type means a higher doping concentration than that of the P type or the N type, and a description of a P− type or an N− type means a lower doping concentration than that of the P type or the N type. Further, in the specification, a description of a P++ type or an N++ type means a higher doping concentration than that of the P+ type or the N+ type. In the specification, a unit system is the SI base unit system unless otherwise particularly noted. Although a unit of length is represented using cm, it may be converted to meters (m) before calculations.

A chemical concentration in the present specification indicates an atomic density of an impurity measured regardless of an electrical activation state. The chemical concentration can be measured by, for example, secondary ion mass spectrometry (SIMS). The net doping concentration described above can be measured by voltage-capacitance profiling (CV profiling). Further, a carrier concentration measured by spreading resistance profiling (SRP method) may be set as the net doping concentration. The carrier concentration measured by the CV profiling or the SRP method may be a value in a thermal equilibrium state. Further, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

When a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping. In the present specification, atoms/cm³ or/cm³ is used to indicate a concentration per unit volume. This unit is used for a concentration of a donor or an acceptor in a semiconductor substrate, or a chemical concentration. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The decrease in carrier mobility occurs when carriers are scattered due to disorder of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorous or arsenic serving as a donor, or an acceptor concentration of boron serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

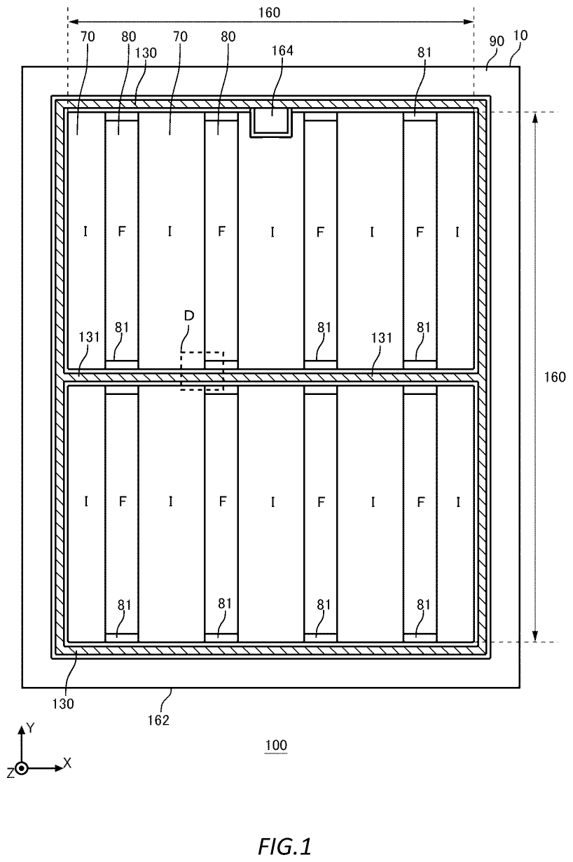

FIG. 1 illustrates a top view showing an example of a semiconductor device 100 according to one embodiment of the present invention. FIG. 1 shows a position at which each member is projected on an upper surface of a semiconductor substrate 10. FIG. 1 shows merely some members of the semiconductor device 100, and omits illustrations of other members.

The semiconductor device 100 includes the semiconductor substrate 10. The semiconductor substrate 10 is a substrate that is formed of a semiconductor material. As an example, the semiconductor substrate 10 is a silicon substrate. The semiconductor substrate 10 has an end side 162 in a top view. When simply referred to as the top view in the present specification, it means that the semiconductor substrate 10 is viewed from an upper surface side. The semiconductor substrate 10 in this example has two sets of end sides 162 opposite to each other in a top view. In FIG. 1, the X axis and the Y axis are parallel to any of the end sides 162. In addition, the Z axis is perpendicular to the upper surface of the semiconductor substrate 10.

The semiconductor substrate 10 is provided with an active portion 160. The active portion 160 is a region where a main current flows in a depth direction between the upper surface and a lower surface of the semiconductor substrate 10 when the semiconductor device 100 operates. An emitter electrode is provided above the active portion 160, but is omitted in FIG. 1. The active portion 160 may refer to a region that overlaps with the emitter electrode in a top view. In addition, a region sandwiched between active portions 160 in a top view may also be included in the active portion 160.

The active portion 160 is provided with at least one of a transistor portion 70 including a transistor element such as an insulated gate bipolar transistor (IGBT) and a diode portion 80 including a diode element such as a freewheeling diode (FWD). In the example shown in FIG. 1, the transistor portions 70 and the diode portions 80 are alternately arranged along a predetermined array direction (the X axis direction in this example) at the upper surface of the semiconductor substrate 10. The semiconductor device 100 in this example is a reverse-conducting IGBT (RC-IGBT).

In FIG. 1, a region where each of the transistor portions 70 is arranged is indicated by a symbol “I”, and a region where each of the diode portions 80 is arranged is indicated by a symbol “F”. In the present specification, a direction perpendicular to the array direction in the top view may be referred to as an extending direction (the Y axis direction in FIG. 1). Each of the transistor portions 70 and the diode portions 80 may have a longitudinal length in the extending direction. In other words, the length of each of the transistor portions 70 in the Y axis direction is larger than the width in the X axis direction. Similarly, the length of each of the diode portions 80 in the Y axis direction is larger than the width in the X axis direction. The extending direction of the transistor portion 70 and the diode portion 80, and the longitudinal direction of each trench portion described below may be the same.

Each of the diode portions 80 includes a cathode region of N+ type in a region in contact with the lower surface of the semiconductor substrate 10. In the present specification, a region where the cathode region is provided is referred to as the diode portion 80. In other words, the diode portion 80 is a region that overlaps with the cathode region in the top view. On the lower surface of the semiconductor substrate 10, a collector region of P+ type may be provided in a region other than the cathode region. In the specification, the diode portion 80 may also include an extension region 81 where the diode portion 80 extends to a gate runner described below in the Y axis direction. The collector region is provided on a lower surface of the extension region 81.

The transistor portion 70 has the collector region of the P+ type in a region in contact with the lower surface of the semiconductor substrate 10. Further, in the transistor portion 70, an emitter region of the N type, a base region of the P type, and a gate structure having a gate conductive portion and a gate dielectric film are periodically arranged on the upper surface side of the semiconductor substrate 10.

The semiconductor device 100 may have one or more pads above the semiconductor substrate 10. The semiconductor device 100 of this example has a gate pad 164. The semiconductor device 100 may have a pad such as an anode pad, a cathode pad, and a current detection pad. Each pad is arranged in a region close to the end side 162. The region close to the end side 162 refers to a region between the end side 162 and the emitter electrode in the top view. When the semiconductor device 100 is mounted, each pad may be connected to an external circuit via a wiring such as a wire.

A gate potential is applied to the gate pad 164. The gate pad 164 is electrically connected to a conductive portion of a gate trench portion of the active portion 160. The semiconductor device 100 includes a gate runner that connects the gate pad 164 and the gate trench portion. In FIG. 1, the gate runner is hatched with diagonal lines.

The gate runner of the present example has an outer circumferential gate runner 130 and an active-side gate runner 131. The outer circumferential gate runner 130 is arranged between the active portion 160 and the end side 162 of the semiconductor substrate 10 in a top view. The outer circumferential gate runner 130 in this example encloses the active portion 160 in a top view. A region enclosed by the outer circumferential gate runner 130 in a top view may be defined as the active portion 160. In addition, a well region is formed below the gate runner. The well region is a P type region having a higher concentration than the base region described below, and is formed up to a position deeper than a position of the base region from the upper surface of the semiconductor substrate 10. A region enclosed by the well region in a top view may be the active portion 160.

An outer circumferential gate runner 130 is connected to the gate pad 164. The outer circumferential gate runner 130 is arranged above the semiconductor substrate 10. The outer circumferential gate runner 130 may be a metal wiring including aluminum or the like.

The active-side gate runner 131 is provided in the active portion 160. Providing the active-side gate runner 131 in the active portion 160 can reduce a variation in a wiring line length from the gate pad 164 for each region of the semiconductor substrate 10.

The outer circumferential gate runners 130 and the active-side gate runner 131 are connected to the gate trench portion of the active portion 160. The outer circumferential gate runners 130 and the active-side gate runner 131 are arranged above the semiconductor substrate 10. The outer circumferential gate runner 130 and the active-side gate runner 131 may be a wiring formed of a semiconductor such as polysilicon doped with an impurity.

The active-side gate runner 131 may be connected to the outer circumferential gate runner 130. The active-side gate runner 131 of this example is provided extending in the X axis direction so as to cross the active portion 160 from one outer circumferential gate runner 130 to the other outer circumferential gate runner 130 substantially at the center of the Y axis direction, the outer circumferential gate runner 130 enclosing the active portion 160. When the active portion 160 is divided by the active-side gate runner 131, the transistor portion 70 and the diode portion 80 may be alternately arranged in the X axis direction in each divided region.

The semiconductor device 100 may include a temperature sensing portion (not shown) that is a PN junction diode formed of polysilicon or the like, and a current detection portion (not shown) that simulates an operation of the transistor portion provided in the active portion 160.

The semiconductor device 100 of this example includes an edge termination structure portion 90 between the active portion 160 and the end side 162 in the top view. The edge termination structure portion 90 of this example is arranged between the outer circumferential gate runner 130 and the end side 162. The edge termination structure portion 90 reduces an electric field strength on the upper surface side of the semiconductor substrate 10. The edge termination structure portion 90 may include at least one of a guard ring, a field plate, and a RESURF which are annularly provided to enclose the active portion 160.

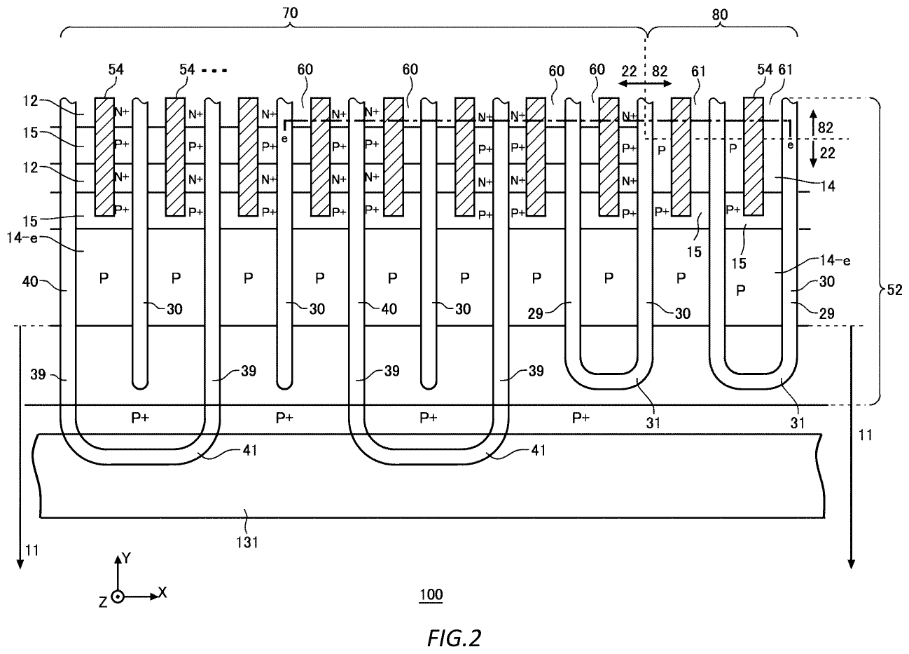

FIG. 2 illustrates an enlarged view of a region D in FIG. 1. The region D is a region including the transistor portion 70, the diode portion 80, and the active-side gate runner 131. The semiconductor device 100 of this example includes a gate trench portion 40, a dummy trench portion 30, a well region 11, an emitter region 12, a base region 14, and a contact region 15 which are provided inside the upper surface side of the semiconductor substrate 10. The gate trench portion 40 and the dummy trench portion 30 each are an example of the trench portion. Further, the semiconductor device 100 of this example includes an emitter electrode 52 and the active-side gate runner 131 that are provided above the upper surface of the semiconductor substrate 10. The emitter electrode 52 and the active-side gate runner 131 are provided in isolation each other.

An interlayer dielectric film is provided between the emitter electrode 52 and the active-side gate runner 131, and the upper surface of the semiconductor substrate 10, but the interlayer dielectric film is omitted in FIG. 2. In the interlayer dielectric film of this example, a contact hole 54 is provided passing through the interlayer dielectric film. In FIG. 2, each contact hole 54 is hatched with the diagonal lines.

The emitter electrode 52 is provided on the upper side of the gate trench portion 40, the dummy trench portion 30, the well region 11, the emitter region 12, the base region 14, and the contact region 15. The emitter electrode 52 is in contact with the emitter region 12, the contact region 15, and the base region 14 on the upper surface of the semiconductor substrate 10, through the contact hole 54. Further, the emitter electrode 52 is connected to a dummy conductive portion in the dummy trench portion 30 through the contact hole provided in the interlayer dielectric film. The emitter electrode 52 may be connected to the dummy conductive portion of the dummy trench portion 30 at an edge of the dummy trench portion 30 in the Y axis direction. The dummy conductive portions of the dummy trench portions 30 may not be connected to the emitter electrode 52 and a gate conductive portion, and may be controlled to be at a potential different from a potential of the emitter electrode 52 and a potential of the gate conductive portion.

The active-side gate runner 131 is connected to the gate trench portion 40 through the contact hole provided in the interlayer dielectric film. The active-side gate runner 131 may be connected to a gate conductive portion of the gate trench portion 40 at an edge portion 41 of the gate trench portion 40 in the Y axis direction. The active-side gate runner 131 is not connected to the dummy conductive portion in the dummy trench portion 30.

The emitter electrode 52 is formed of a material including a metal. FIG. 2 shows a range where the emitter electrode 52 is provided. For example, at least a part of a region of the emitter electrode 52 is formed of aluminum or an aluminum-silicon alloy, for example, a metal alloy such as AlSi, AlSiCu. The emitter electrode 52 may have a barrier metal formed of titanium, a titanium compound, or the like below a region formed of aluminum or the like. Further, a plug, which is formed by embedding tungsten or the like so as to be in contact with the barrier metal and aluminum or the like, may be included in the contact hole.

The well region 11 is provided overlapping the active-side gate runner 131. The well region 11 is provided so as to extend with a predetermined width even in a range not overlapping the active-side gate runner 131. The well region 11 of this example is provided away from an end of the contact hole 54 in the Y axis direction toward the active-side gate runner 131 side. The well region 11 is a second conductivity type region in which the doping concentration is higher than the base region 14. The base region 14 of this example is a P type, and the well region 11 is a P+ type.

Each of the transistor portion 70 and the diode portion 80 includes a plurality of trench portions arranged in the array direction. In the transistor portion 70 of this example, one or more gate trench portions 40 and one or more dummy trench portions 30 are alternately provided along the array direction. In the diode portion 80 of this example, the plurality of dummy trench portions 30 are provided along the array direction. In the diode portion 80 of this example, the gate trench portion 40 is not provided.

The gate trench portion 40 of this example may have two linear portions 39 extending along the extending direction perpendicular to the array direction (portions of a trench that are linear along the extending direction), and the edge portion 41 connecting the two linear portions 39. The extending direction in FIG. 2 is the Y axis direction.

At least a part of the edge portion 41 is desirably provided in a curved shape in a top view. By connecting between end portions of the two linear portions 39 in the Y axis direction by the edge portion 41, it is possible to reduce the electric field strength at the end portions of the linear portions 39.

In the transistor portion 70, the dummy trench portions 30 are provided between the respective linear portions 39 of the gate trench portions 40. Between the respective linear portions 39, one dummy trench portion 30 may be provided, or a plurality of dummy trench portions 30 may be provided. The dummy trench portion 30 may have a linear shape extending in the extending direction, or may have linear portions 29 and an edge portion 31 similar to the gate trench portion 40. The semiconductor device 100 shown in FIG. 2 includes both of the linear dummy trench portion 30 having no edge portion 31, and the dummy trench portion 30 having the edge portion 31.

A diffusion depth of the well region 11 may be deeper than the depth of the gate trench portion 40 and the dummy trench portion 30. The end portions in the Y axis direction of the gate trench portion 40 and the dummy trench portion 30 are provided in the well region 11 in a top view. In other words, the bottom in the depth direction of each trench portion is covered with the well region 11 at the end portion in the Y axis direction of each trench portion. With this configuration, the electric field strength on the bottom portion of each trench portion can be reduced.

A mesa portion is provided between the respective trench portions in the array direction. The mesa portion refers to a region sandwiched between the trench portions inside the semiconductor substrate 10. As an example, an upper end of the mesa portion is the upper surface of the semiconductor substrate 10. The depth position of the lower end of the mesa portion is the same as the depth position of the lower end of the trench portion. The mesa portion of this example is provided extending in the extending direction (the Y axis direction) along the trench portion, on the upper surface of the semiconductor substrate 10. In this example, a mesa portion 60 is provided in the transistor portion 70, and a mesa portion 61 is provided in the diode portion 80. In the case of simply mentioning “mesa portion” in the present specification, the portion refers to each of the mesa portion 60 and the mesa portion 61.

Each mesa portion is provided with the base region 14. In the mesa portion, a region arranged closest to the active-side gate runner 131, in the base region 14 exposed on the upper surface of the semiconductor substrate 10, is to be a base region 14-e. While FIG. 2 shows the base region 14-e arranged at one end portion of each mesa portion in the extending direction, the base region 14-e is also arranged at the other end portion of each mesa portion. Each mesa portion may be provided with at least one of a first conductivity type of emitter region 12, and a second conductivity type of contact region 15 in a region sandwiched between the base regions 14-e in the top view. The emitter region 12 of this example is an N+ type, and the contact region 15 is a P+ type. The emitter region 12 and the contact region 15 may be provided between the base region 14 and the upper surface of the semiconductor substrate 10 in the depth direction.

The mesa portion 60 of the transistor portion 70 has the emitter region 12 exposed on the upper surface of the semiconductor substrate 10. The emitter region 12 is provided in contact with the gate trench portion 40. The mesa portion 60 in contact with the gate trench portion 40 may be provided with the contact region 15 exposed on the upper surface of the semiconductor substrate 10.

Each of the contact region 15 and the emitter region 12 in the mesa portion 60 is provided from one trench portion to the other trench portion in the X axis direction. As an example, the contact region 15 and the emitter region 12 in the mesa portion 60 are alternately arranged along the extending direction of the trench portion (the Y axis direction).

In another example, the contact region 15 and the emitter region 12 in the mesa portion 60 may be provided in a stripe shape along the extending direction of the trench portion (the Y axis direction). For example, the emitter region 12 is provided in a region in contact with the trench portion, and the contact region 15 is provided in a region sandwiched between the emitter regions 12.

The mesa portion 61 of the diode portion 80 is not provided with the emitter region 12. The base region 14 and the contact region 15 may be provided on an upper surface of the mesa portion 61. In the region sandwiched between the base regions 14-e on the upper surface of the mesa portion 61, the contact region 15 may be provided in contact with each base region 14-e. The base region 14 may be provided in a region sandwiched between the contact regions 15 on the upper surface of the mesa portion 61. The base region 14 may be arranged in the entire region sandwiched between the contact regions 15.

The contact hole 54 is provided above each mesa portion. The contact hole 54 is arranged in the region sandwiched between the base regions 14-e. The contact hole 54 of this example is provided above respective regions of the contact region 15, the base region 14, and the emitter region 12. The contact hole 54 is not provided in regions corresponding to the base region 14-e and the well region 11. The contact hole 54 may be arranged at the center of the mesa portion 60 in the array direction (the X axis direction).

In the diode portion 80, a cathode region 82 of the N+ type is provided in a region in

direct contact with the lower surface of the semiconductor substrate 10. On the lower surface of the semiconductor substrate 10, a collector region of the P+ type 22 may be provided in a region where the cathode region 82 is not provided. The cathode region 82 and the collector region 22 are provided between a lower surface 23 of the semiconductor substrate 10 and a buffer region 20. In FIG. 2, a boundary between the cathode region 82 and the collector region 22 is indicated by a dotted line.

The cathode region 82 is arranged away from the well region 11 in the Y axis direction. With this configuration, the distance between the P type region (the well region 11) having a relatively high doping concentration and formed up to the deep position, and the cathode region 82 is ensured, so that the breakdown voltage can be improved. The end portion in the Y axis direction of the cathode region 82 of this example is arranged farther away from the well region 11 than the end portion in the Y axis direction of the contact hole 54. In another example, the end portion in the Y axis direction of the cathode region 82 may be arranged between the well region 11 and the contact hole 54.

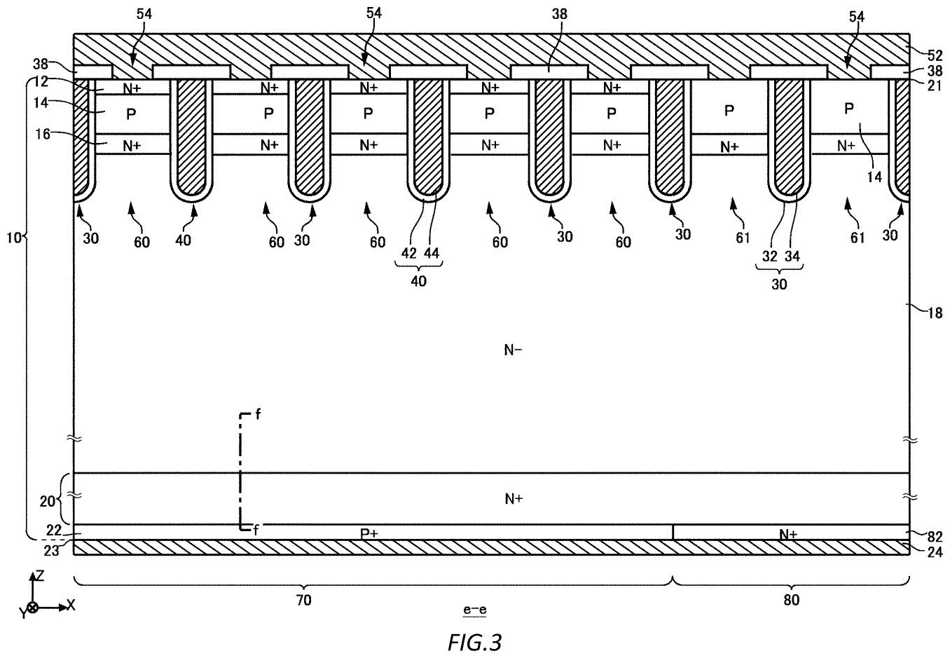

FIG. 3 illustrates an example of a cross section e-e in FIG. 2. The cross section e-e is the XZ plane passing through an emitter region 12 and a cathode region 82. A semiconductor device 100 in this example includes a semiconductor substrate 10, an interlayer dielectric film 38, an emitter electrode 52, and a collector electrode 24 in the cross section.

The interlayer dielectric film 38 is provided on the upper surface of the semiconductor substrate 10. The interlayer dielectric film 38 is a film including at least one layer of a dielectric film such as silicate glass to which an impurity such as boron or phosphorous is added, a thermal oxide film, and other dielectric films. The interlayer dielectric film 38 is provided with the contact hole 54 described in FIG. 2.

The emitter electrode 52 is provided on the upper side of the interlayer dielectric film 38. The emitter electrode 52 is in contact with an upper surface 21 of the semiconductor substrate 10 through the contact hole 54 of the interlayer dielectric film 38. The collector electrode 24 is provided on a lower surface 23 of the semiconductor substrate 10. The emitter electrode 52 and the collector electrode 24 are formed of a metal material such as aluminum. In the specification, the direction in which the emitter electrode 52 is connected to the collector electrode 24 (the Z axis direction) is referred to as a depth direction.

The semiconductor substrate 10 includes an N type or N− type of drift region 18. The drift region 18 is provided in each of the transistor portion 70 and the diode portion 80.

In the mesa portion 60 of the transistor portion 70, an N+ type of emitter region 12 and a P type of base region 14 are provided in order from an upper surface 21 side of the semiconductor substrate 10. The drift region 18 is provided below the base region 14. The mesa portion 60 may be provided with an N+ type of accumulation region 16. The accumulation region 16 is arranged between the base region 14 and the drift region 18.

The emitter region 12 is exposed on the upper surface 21 of the semiconductor substrate 10 and is provided in contact with gate trench portion 40. The emitter region 12 may be in contact with the trench portions on both sides of the mesa portion 60. The emitter region 12 has a higher doping concentration than the drift region 18.

The base region 14 is provided below the emitter region 12. The base region 14 of this example is provided in contact with the emitter region 12. The base region 14 may be in contact with the trench portions on both sides of the mesa portion 60.

The accumulation region 16 is provided below the base region 14. The accumulation region 16 is an N+ type region with a higher doping concentration than the drift region 18. That is, the accumulation region 16 has a higher donor concentration than the drift region 18. By providing the accumulation region 16 having the high concentration between the drift region 18 and the base region 14, it is possible to improve a carrier injection enhancement effect (IE effect) and reduce an on-voltage. The accumulation region 16 may be provided to cover a whole lower surface of the base region 14 in each mesa portion 60.

The mesa portion 61 of the diode portion 80 is provided with the P type of base region 14 in contact with the upper surface 21 of the semiconductor substrate 10. The drift region 18 is provided below the base region 14. In the mesa portion 61, the accumulation region 16 may be provided below the base region 14.

In each of the transistor portion 70 and the diode portion 80, an N+ type buffer region 20 may be provided below the drift region 18. The doping concentration of the buffer region 20 is higher than the doping concentration of the drift region 18. The buffer region 20 may have a concentration peak having a higher doping concentration than the doping concentration of the drift region 18. The doping concentration of the concentration peak indicates a doping concentration at the local maximum of the concentration peak. Further, as the doping concentration of the drift region 18, an average value of doping concentrations in the region where the doping concentration distribution is substantially flat may be used.

The buffer region 20 in this example may have two or more concentration peaks in the depth direction (the Z axis direction) of the semiconductor substrate 10. The concentration peak of the buffer region 20 may be provided at the same depth position as, for example, a chemical concentration peak of hydrogen (a proton) or phosphorus. The buffer region 20 may function as a field stopper layer which prevents a depletion layer expanding from the lower end of the base region 14 from reaching the collector region of the P+ type 22 and the cathode region 82 of the N+ type.

In the transistor portion 70, the collector region 22 of the P+ type is provided below the buffer region 20. An acceptor concentration of the collector region 22 is higher than an acceptor concentration of the base region 14. The collector region 22 may include an acceptor which is the same as or different from an acceptor of the base region 14. The acceptor of the collector region 22 is, for example, boron.

Below the buffer region 20 in the diode portion 80, the cathode region 82 of the N+ type is provided. A donor concentration of the cathode region 82 is higher than a donor concentration of the drift region 18. A donor of the cathode region 82 is, for example, hydrogen or phosphorus. Note that an element serving as a donor and an acceptor in each region is not limited to the example described above. The collector region 22 and the cathode region 82 are exposed on the lower surface 23 of the semiconductor substrate 10 and are connected to the collector electrode 24. The collector electrode 24 may be in contact with the entire lower surface 23 of the semiconductor substrate 10. The emitter electrode 52 and the collector electrode 24 are formed of a metal material such as aluminum.

One or more gate trench portions 40 and one or more dummy trench portions 30 are provided on the upper surface 21 side of the semiconductor substrate 10. Each of the trench portions is provided from the upper surface 21 of the semiconductor substrate 10 through the base region 14 to below the base region 14. In a region where at least any one of the emitter region 12, the contact region 15, and the accumulation region 16 is provided, each trench portion also penetrates the doping regions of these. The configuration of the trench portion penetrating the doping region is not limited to the one manufactured in the order of forming the doping region and then forming the trench portion. The configuration of the trench portions penetrating the doping region also includes a configuration of forming the trench portions and then forming the doping region between the trench portions.

As described above, the transistor portion 70 is provided with the gate trench portion 40 and the dummy trench portion 30. In the diode portion 80, the dummy trench portion 30 is provided, and the gate trench portion 40 is not provided. The boundary in the X axis direction between the diode portion 80 and the transistor portion 70 in this example is the boundary between the cathode region 82 and the collector region 22.

The gate trench portion 40 includes a gate trench provided in the upper surface 21 of the semiconductor substrate 10, a gate dielectric film 42, and a gate conductive portion 44. The gate dielectric film 42 is provided to cover the inner wall of the gate trench. The gate dielectric film 42 may be formed by oxidizing or nitriding a semiconductor on the inner wall of the gate trench. The gate conductive portion 44 is provided inside from the gate dielectric film 42 in the gate trench. That is, the gate dielectric film 42 insulates the gate conductive portion 44 from the semiconductor substrate 10. The gate conductive portion 44 is formed of a conductive material such as polysilicon.

The gate conductive portion 44 may be provided longer than the base region 14 in the depth direction. The gate trench portion 40 in the cross section is covered by the interlayer dielectric film 38 on the upper surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary in contact with the gate trench portion 40.

The dummy trench portions 30 may have the same structure as the gate trench portions 40 in the cross section. The dummy trench portion 30 includes a dummy trench provided in the upper surface 21 of the semiconductor substrate 10, a dummy dielectric film 32, and a dummy conductive portion 34. The dummy conductive portion 34 is electrically connected to the emitter electrode 52. The dummy dielectric film 32 is provided covering an inner wall of the dummy trench. The dummy conductive portion 34 is provided in the dummy trench, and is provided inside the dummy dielectric film 32. The dummy dielectric film 32 insulates the dummy conductive portion 34 from the semiconductor substrate 10. The dummy conductive portion 34 may be formed of the same material as the gate conductive portion 44. For example, the dummy conductive portion 34 is formed of a conductive material such as polysilicon or the like. The dummy conductive portion 34 may have the same length as the gate conductive portion 44 in the depth direction.

The gate trench portion 40 and the dummy trench portion 30 in this example are covered with the interlayer dielectric film 38 on the upper surface 21 of the semiconductor substrate 10. Note that the bottom portions of the dummy trench portion 30 and the gate trench portion 40 may be formed in a curved-surface shape (a curved shape in the cross section) convexly downward.

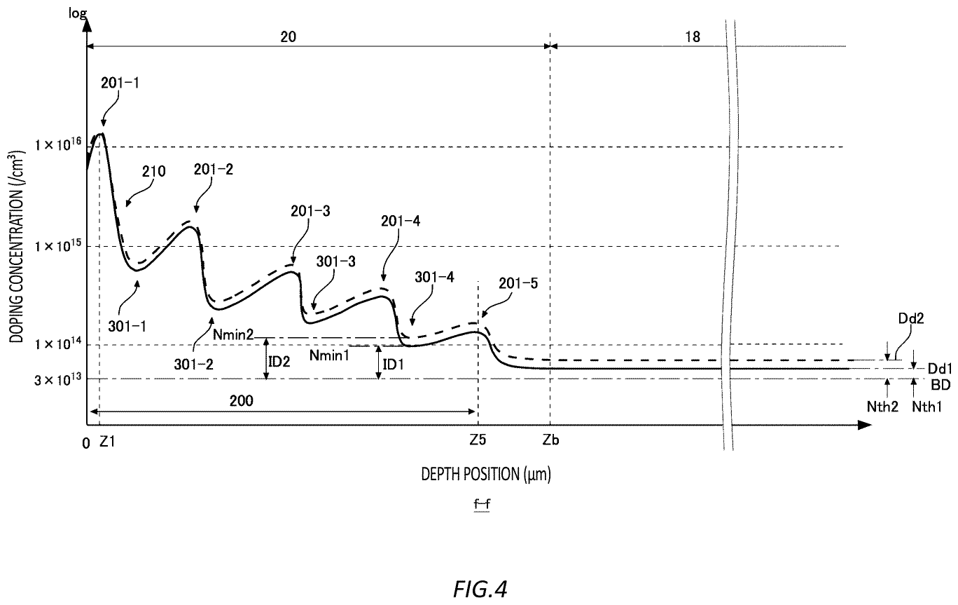

FIG. 4 illustrates a reference example of distribution 210 of doping concentrations on the line f-f of FIG. 3. In the graphs, such as FIG. 4, of concentration distributions, a carrier concentration measured by SRP method or the like is represented as the doping concentration. The line f-f is a line parallel to the Z axis that passes through the buffer region 20. A horizontal axis in FIG. 4 shows a depth position (a position in the Z axis direction) in the semiconductor substrate 10. In the graphs, such as FIG. 4, of concentration distributions, the lower end position of the buffer region 20 is defined as a reference position (0) in the Z axis direction and a distance from the reference position is defined as a position in the Z axis direction. At the lower end position of the buffer region 20, a trough of the doping concentration distribution due to the PN junction of the collector region 22 and the buffer region 20 is present, although the trough is omitted in FIG. 4 or the like.

Oxygen is included in the entire semiconductor substrate 10. FIG. 4 shows the distribution 210 when the semiconductor device 100 is formed on each of two semiconductor substrates 10 having different oxygen chemical concentrations from each other. In FIG. 4, a dashed-line distribution represents an example in which the oxygen chemical concentration in the semiconductor substrate 10 is relatively high (for example, 4×10¹⁷ atoms/cm³) whereas a solid-line distribution represents an example in which the oxygen chemical concentration in the semiconductor substrate 10 is relatively low (for example, 1×10¹⁷ atoms/cm³). Comparison of the oxygen chemical concentrations of the semiconductor substrates 10 may be performed using an average value of the oxygen chemical concentration in the entire substrate or a maximum value of the oxygen chemical concentration. In respective examples, the dose amount and the acceleration energy of dopant implanted locally into the buffer region 20 are the same. The dopant implanted into the buffer region 20 is a proton, for example, but not limited to this.

In either example, one or more doping concentration peaks 201 are provided in the buffer region 20. In the example of FIG. 4, five doping concentration peaks 201-1 to 201-5 are provided in the buffer region 20. In the present specification, among the doping concentration peaks 201 in the buffer region 20, the doping concentration peak 201 farthest away from the lower surface 23 of the semiconductor substrate 10 (in FIG. 4, the doping concentration peak 201-5) may be referred to as the deepest peak and the doping concentration peak 201 closest to the lower surface 23 (in FIG. 4, the doping concentration peak 201-1) may be referred to as the shallowest peak. In addition, the depth position at the local maximum of the doping concentration peak 201-1 is defined as Z1, and the depth position at the local maximum of the doping concentration peak 201-5 is defined as Z5. An inter-peak region 301 is provided between adjacent doping concentration peaks 201 in the buffer region 20. A plurality of inter-peak regions 301 may be provided. In the present specification, among the inter-peak regions 301 in the buffer region 20, the inter-peak region 301 farthest away from the lower surface 23 of the semiconductor substrate 10 (in FIG. 4, the inter-peak region 301-4) may be referred to as the deepest inter-peak region and the inter-peak region 301 closest to the lower surface 23 (in FIG. 4, the inter-peak region 301-1) may be referred to as the shallowest inter-peak region, in some cases.

The drift region 18 is provided above the buffer region 20. The depth position at the boundary between the buffer region 20 and the drift region 18 is defined as Zb. The depth position Zb is a position at which the doping concentration firstly becomes identical to the doping concentration (Dd1 or Dd2) in the drift region 18 in the direction from the buffer region 20 to the drift region 18. No local dopant has been implanted in the drift region 18. The doping concentration of the drift region 18 may be substantially constant. The thermal donor has been formed in the entire semiconductor substrate 10 due to the influence of heat applied on the semiconductor substrate 10. The distribution of the thermal donor is substantially uniform throughout the entire semiconductor substrate 10. Thus, the doping concentration of the drift region 18 becomes slightly higher than the bulk donor concentration BD. The oxygen included in the semiconductor substrate 10 forms an unstable oxygen complex in the course of temperature rise or fall of the semiconductor substrate 10. The oxygen complex acts as a dopant in the semiconductor substrate 10. In the present specification, the oxygen complex is referred to as the thermal donor.

The concentration of the thermal donor formed in each position of the semiconductor substrate 10 varies according to the concentration of oxygen included in the semiconductor substrate 10 and the condition of the temperature rise and fall of the semiconductor substrate 10. As shown in FIG. 4, the concentration of the thermal donor formed is different and the doping concentration is varied in the entire semiconductor substrate 10 between the two examples having different oxygen chemical concentrations of the semiconductor substrate 10.

The doping concentration of the drift region 18 in the solid-line distribution 210 of the semiconductor substrate 10 with the relatively low oxygen chemical concentration is defined as Dd1 whereas the doping concentration of the drift region 18 in the dashed-line distribution 210 of the semiconductor substrate 10 with the relatively high oxygen chemical concentration is defined as Dd2. As the doping concentration of each drift region 18, an average value thereof in the entire drift region 18 may be used or a minimum value may be used.

The concentration of the thermal donor in the solid-line distribution 210 of the semiconductor substrate 10 with the relatively low oxygen chemical concentration is defined as Nth1 whereas the concentration of the thermal donor in the dashed-line distribution 210 of the semiconductor substrate 10 with the relatively high oxygen chemical concentration is defined as Nth2. A difference (Dd1−BD or Dd2−BD) between the doping concentration (Dd1 or Dd2) in the drift region 18 and the bulk donor concentration BD corresponds to the concentration (Nth1 or Nth2) of the thermal donor formed in respective semiconductor substrates 10. In each example described in the present specification, the difference between the doping concentration of the drift region 18 and the bulk donor concentration BD is defined as the concentration of the thermal donor. The concentration of the thermal donor may be the same throughout the entire semiconductor substrate 10.

As the bulk donor concentration BD, a minimum value of the chemical concentration of the bulk donor in the semiconductor substrate 10 may be used, the chemical concentration of the bulk donor at a center position in the depth direction of the semiconductor substrate 10 may be used, or an average value of the chemical concentration of the bulk donor in the drift region 18 may be used. The bulk donor is a dopant that is other than oxygen and is distributed throughout the entire semiconductor substrate 10. For example, the bulk donor may be phosphorus, arsenic, or antimony, but is not limited to these. If both the P type bulk acceptor and the N type bulk donor are distributed throughout the entire semiconductor substrate 10, the bulk donor concentration BD is the net concentration determined by the difference between the concentration of the bulk donor and the concentration of the bulk acceptor. As the concentrations of the bulk donor and the bulk acceptor, a value measured by the SIMS method or the like may be used.

The buffer region 20 includes an increased donor in addition to the bulk donor. The increased donor is a donor other than the bulk donor. The increased donor includes an implanted donor formed by locally implanting ions into the buffer region 20 and the above-described thermal donor. When a hydrogen ion is locally implanted into the buffer region 20, the implanted donor is the hydrogen donor. When phosphorus or the like is locally implanted into the buffer region 20, the implanted donor is the phosphorus donor.

The concentration of the thermal donor varies according to the oxygen concentration in the semiconductor substrate 10. Thus, if a ratio of the thermal donor concentration included in the increased donor is high, the concentration of the increased donor varies according to the oxygen concentration in the semiconductor substrate 10. Accordingly, as shown by the dashed-line and the solid-line distributions 210 in FIG. 4, the doping concentration of the buffer region 20 varies according to the oxygen concentration in the semiconductor substrate 10.

In the buffer region 20, a range from the lower end of the buffer region 20 to the deepest peak (the doping concentration peak 201-5 in the present example) is defined as a first range 200. In the solid-line distribution 210, the minimum value of the doping concentration of the first range 200 is defined as Nmin1, and the concentration of the increased donor at this depth position is defined as ID1. The minimum value Nmin1 of the doping concentration in the first range 200 of the present example is the doping concentration Nmin1 at the deepest inter-peak region (the inter-peak region 301-4 in the present example). The concentration ID1 of the increased donor is a difference (Nmin1−BD) between the doping concentration Nmin1 and the bulk donor concentration BD. In addition, in the dashed-line distribution 210, the minimum value of the doping concentration in the first range 200 is defined as Nmin2, and the concentration of the increased donor at this depth position is defined as ID2. The depth position at which the doping concentration becomes Nmin1 in the solid-line distribution 210 is substantially the same as the depth position at which the doping concentration becomes Nmin2 in the dashed-line distribution 210. The concentration ID2 of the increased donor is a difference (Nmin2−BD) between the doping concentration Nmin2 and the bulk donor concentration BD. Note that, some of the inter-peak regions 301 may have a doping concentration lower than the bulk donor concentration BD, in some cases. In such a case, the doping concentration of the inter-peak region 301 having the minimum doping concentration among the inter-peak regions 301 having the doping concentrations higher than the bulk donor concentration BD may be defined as Nmin1.

As the concentrations ID1 and ID2 of the increased donor, the minimum value of the concentration of the increased donor in the first range 200 may be represented. The concentrations Nth1 and Nth2 of the thermal donor are substantially constant at each depth position in the buffer region 20, and thus the ratio of the concentrations Nth1 and Nth2 of the thermal donor relative to the concentrations ID1 and ID2 of the increased donor represents the maximum value of the ratio of thermal donor/increased donor in the first range 200. An average value of the thermal donor concentrations in the drift region 18 may be used as the thermal donor concentration of the buffer region 20, the maximum value of the thermal donor concentrations in the drift region 18 may be used as the thermal donor concentration of the buffer region 20, or the thermal donor concentration at the depth position Zb may be used as the thermal donor concentration of the buffer region 20.

In the solid-line distribution 210, the concentration ID1 of the increased donor is 7×10¹³/cm³ and the concentration Nth1 of the thermal donor is 2×10¹³/cm³. The ratio Nth1/ID1 of the thermal donor relative to the increased donor is 29%. In the dashed-line distribution 210, the concentration ID2 of the increased donor is 1×10¹⁴/cm³ and the concentration Nth2 of the thermal donor is 5×10¹³/cm³. The ratio Nth2/ID2 of the thermal donor relative to the increased donor is 50%. In this manner, larger ratio of the thermal donor relative to the increased donor causes significant dispersion in the concentration of the increased donor according to the oxygen concentration of the semiconductor substrate 10. For example, this causes the characteristics of the semiconductor device 100, such as breakdown voltage, to vary. When the breakdown voltage of the example of the solid-line distribution 210 is normalized to 1, the breakdown voltage of the example of the dashed-line distribution 210 is 1.15.

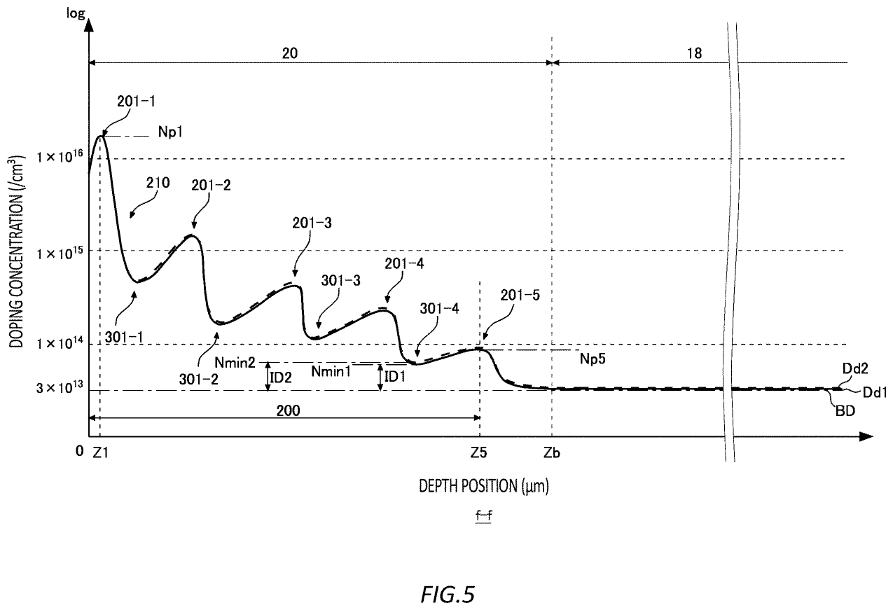

FIG. 5 illustrates distribution 210 of doping concentrations according to the example. In the example of FIG. 5, the concentration of the thermal donor formed in the semiconductor substrate 10 is lower than that in the example of FIG. 4. Thus, the doping concentration and the concentration of the increased donor at the respective depth positions are also different from those in the example of FIG. 4. Other structures are similar to those of the example shown in FIG. 4. Again in FIG. 5, a dashed line represents a distribution 210 of the example in which the oxygen chemical concentration in the semiconductor substrate 10 is relatively high (for example, 4×10¹⁷ atoms/cm³) whereas a solid line represents a distribution 210 of the example in which the oxygen chemical concentration in the semiconductor substrate 10 is relatively low (for example, 1×10¹⁷ atoms/cm³). In the example of FIG. 5, although the oxygen chemical concentration included in the semiconductor substrate 10 is similar to that in the example of FIG. 4, the concentration of the thermal donor is controlled to be low by controlling the thermal history relative to the semiconductor substrate 10.

As described above, the bulk donor and the thermal donor are included in the semiconductor substrate 10. The bulk donor and the thermal donor may be distributed throughout the entire semiconductor substrate 10. The drift region 18 includes the bulk donor and the thermal donor. No other donors may be distributed in the drift region 18.

The buffer region 20 includes the bulk donor and the increased donor. As described above, the increased donor includes the implanted donor and the thermal donor. The implanted donor may be a hydrogen donor, a phosphorus donor, or other donors. The hydrogen donor may include a CiOi-H donor. The hydrogen donor may include a VOH defect or an interstitial Si—H.

In the present example, the thermal donor concentration Nth is 10% or less of the concentration ID of the increased donor at the same depth position throughout the entire first range 200 in both the solid-line and dashed-line distributions 210. Again in the example of FIG. 5, in the solid-line distribution 210, the minimum value of the doping concentration in the first range 200 is defined as Nmin1, and the concentration of the increased donor at this depth position is defined as ID1. The concentration ID1 of the increased donor is a difference (Nmin1−BD) between the doping concentration Nmin1 and the bulk donor concentration BD. In addition, in the dashed-line distribution 210, the minimum value of the doping concentration in the first range 200 is defined as Nmin2, and the concentration of the increased donor at this depth position is defined as ID2.

As an example, in the solid-line distribution 210, the concentration ID1 of the increased donor is 5×10¹³/cm³ and the concentration Nth1 of the thermal donor is 3×10¹²/cm³. The ratio Nth1/ID1 of the thermal donor relative to the increased donor is 6%. In the dashed-line distribution 210, the concentration ID2 of the increased donor is 5×10¹³/cm³ and the concentration Nth2 of the thermal donor is 5×10¹²/cm³. The ratio Nth2/ID2 of the thermal donor relative to the increased donor is 10%. That is, in both examples, the concentration Nth of the thermal donor is 10% or less of the concentration ID of the increased donor at the same depth position throughout the entire first range 200.

In the present example, reduction in the ratio of the thermal donor is enabling

suppression of the dispersion of the concentration of the increased donor caused by the oxygen concentration in the semiconductor substrate 10. Thus, variations in the characteristics, such as breakdown voltage, of the semiconductor device 100 can be suppressed. In the example of FIG. 5, when the breakdown voltage of the example of the solid-line distribution 210 is defined as 1, the breakdown voltage of the example of the dashed-line distribution 210 is 1.02.

Throughout the entire first range 200, the concentration Nth of the thermal donor may be 10% or less, 8% or less, 6% or less, or 5% or less of the concentration ID of the increased donor at the same depth position. By reducing the ratio of the thermal donor, the dispersion of the doping concentration of the buffer region 20 can be suppressed and thus the characteristic variation of the semiconductor device 100 can be suppressed. Throughout the entire first range 200, the concentration Nth of the thermal donor may be 0.1% or more, 0.5% or more, 1% or more, 2% or more, 3% or more, or 5% or more of the concentration ID of the increased donor at the same depth position.

The oxygen chemical concentration of the semiconductor substrate 10 is 1×10¹⁶ atoms/cm³ or more. In the present example, even when the oxygen chemical concentration of the semiconductor substrate 10 is high, the variation in the characteristics, such as breakdown voltage, of the semiconductor device 100 can be suppressed by suppressing the generation of the thermal donor. Thus, there is no need to prepare the substrate with low oxygen chemical concentration, allowing a reduction in the manufacturing cost of the semiconductor device 100. In addition, by using the semiconductor substrate 10 with a high oxygen chemical concentration, the hydrogen donor is formed more easily, and the doping concentration of the buffer region 20 is increased more easily. The oxygen chemical concentration of the semiconductor substrate 10 may be 5×10¹⁶ atoms/cm³ or more, 5×10¹⁶ atoms/cm³ or more, or 1×10¹⁷ atoms/cm³ or more. The oxygen chemical concentration of the semiconductor substrate 10 may be 1×10¹⁸ atoms/cm³ or less, or 5×10¹⁷ atoms/cm³ or less.

The concentration (Nth1 or Nth2) of the thermal donor in the drift region 18 may be equal to or less than 0.0001 times (1×10⁻⁴ times) the oxygen chemical concentration of the drift region 18. As the oxygen chemical concentration of the drift region 18, an average value in the drift region 18 may be used, a minimum value may be used or a value at the center in the depth direction of the drift region 18 may be used. This allows reduction in the ratio of the thermal donor relative to the increased donor in the buffer region 20, and thus the characteristic variation of the semiconductor device 100 can be suppressed. The concentration (Nth1 or Nth2) of the thermal donor in the drift region 18 may be equal to or less than 0.00005 times (5×10⁻⁵ times) or equal to or less than 0.00001 times (1×10⁻⁵ times) the oxygen chemical concentration of the drift region 18. The concentration (Nth1 or Nth2) of the thermal donor in the drift region 18 may be equal to or more than 1×10⁻⁸ times, equal to or more than 5×10⁻⁸ times, or equal to or more than 1×10⁻⁷ times the oxygen chemical concentration of the drift region 18.

The doping concentration (Dd1 or Dd2) in the drift region 18 may be equal to or less than 1.5 times the concentration BD of the bulk donor. This allows reduction in the ratio of the thermal donor relative to the increased donor in the buffer region 20, and thus the characteristic variation of the semiconductor device 100 can be suppressed. The doping concentration (Dd1 or Dd2) in the drift region 18 may be equal to or less than 1.3 times or equal to or less than 1.1 times the concentration BD of the bulk donor. The doping concentration (Dd1 or Dd2) in the drift region 18 is higher than the concentration BD of the bulk donor.

The concentration (Nth1 or Nth2) of the thermal donor in the drift region 18 may be equal to or less than 0.5 times the concentration BD of the bulk donor. This allows reduction in the ratio of the thermal donor relative to the increased donor in the buffer region 20, and thus the characteristic variation of the semiconductor device 100 can be suppressed. The concentration (Nth1 or Nth2) of the thermal donor in the drift region 18 may be equal to or less than 0.3 times or equal to or less than 0.1 times the concentration BD of the bulk donor. The concentration (Nth1 or Nth2) of the thermal donor in the drift region 18 is higher than 0.

At the depth position Z5 of the local maximum of the deepest peak (the doping

concentration peak 201-5 in the present example), the concentration Nth of the thermal donor may be equal to or less than 0.1 times the doping concentration Np5. In the solid-line and dashed-line distributions 210, the values of the doping concentration Np5 are substantially the same. This allows reduction in the ratio of the thermal donor relative to the increased donor at the deepest peak in the buffer region 20, and thus the characteristic variation of the semiconductor device 100 can be suppressed. For example, the dispersion of oscillation of the voltage waveform when the space-charge region (or a depletion layer) spreading from the upper surface 21 side reaches the buffer region 20, can be suppressed at the time of turnoff or the like of the semiconductor substrate 10. At the depth position Z5, the concentration Nth of the thermal donor may be equal to or less than 0.05 times or equal to or less than 0.01 times the doping concentration Np5.

The buffer region 20 includes a maximum peak (the doping concentration peak 201-1 in the present example) at which the doping concentration is maximum among the doping concentration peaks 201 other than the deepest peak. A peak other than the doping concentration peak 201-1 may be the maximum peak. For example, the doping concentration peak 201-2 may be the maximum peak. The concentration of the thermal donor at the depth position Z1 of the local maximum of the maximum peak may be equal to or less than 0.01 times the doping concentration Np1. This allows reduction in the ratio of the thermal donor relative to the increased donor at the maximum peak in the buffer region 20, and thus the characteristic variation of the semiconductor device 100 can be suppressed. At the depth position Z1, the concentration of the thermal donor may be equal to or less than 0.005 times or equal to or less than 0.001 times the doping concentration Np1.

The buffer region 20 includes the shallowest peak (the doping concentration peak 201-1 in the present example) that is closest to the lower surface 23 of the semiconductor substrate 10. The concentration of the thermal donor at the depth position Z1 of the local maximum of the shallowest peak may be equal to or less than 0.001 times the doping concentration Np1. This allows reduction in the ratio of the thermal donor relative to the increased donor at the shallowest peak in the buffer region 20, and thus the characteristic variation of the semiconductor device 100 can be suppressed. At the depth position Z1, the concentration of the thermal donor may be equal to or less than 0.0005 times or equal to or less than 0.0001 times the doping concentration Np1.

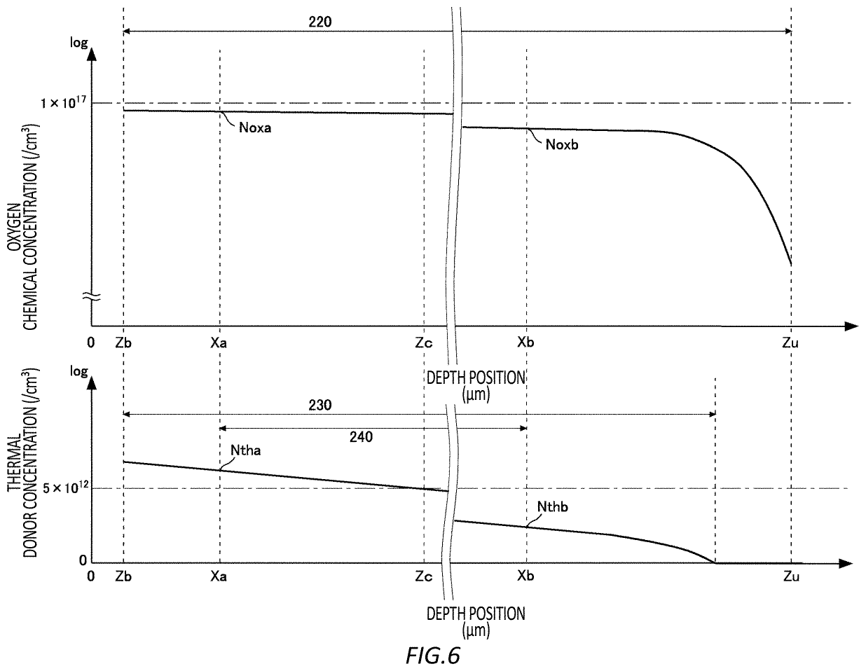

FIG. 6 illustrates an example of the oxygen chemical concentration distribution and the

thermal donor concentration distribution in a region on the upper surface 21 side (a region from a depth position Zb to a depth position Zu) relative to the buffer region 20. As the oxygen chemical concentration, a value measured by the SIMS method or the like may be used. In the present example, the depth position Zb is a boundary position between the buffer region 20 and the drift region 18, and the depth position Zu is an upper end position of the drift region 18.

In the present example, the concentration of the thermal donor is not constant in the depth direction. The concentration of the thermal donor at each depth position in the drift region 18 can be calculated from the difference between the doping concentration and the bulk donor concentration BD. Note that, as the concentration of the thermal donor in the buffer region 20 as described in FIG. 5 or the like, an average value of the thermal donor in the drift region 18 as shown in FIG. 6 may be used or a value of the thermal donor at the depth position Zb may be used.

The oxygen chemical concentration distribution of the present example includes a decreasing portion 220 in which the oxygen chemical concentration decreases toward the upper surface 21 of the semiconductor substrate 10 in the region from the depth position Zb to the depth position Zu. In the decreasing portion 220, the oxygen chemical concentration decreases as the distance to the upper surface 21 is reduced. The decreasing portion 220 does not include a region in which the oxygen chemical concentration increases as the distance to the upper surface 21 is reduced.

The oxygen inside the semiconductor substrate 10 may be released to the outside of the semiconductor substrate 10 in the manufacturing process or the like of the semiconductor device 100. Thus, the oxygen chemical concentration decreases significantly in the vicinity of the surface of the semiconductor substrate 10, and the oxygen chemical concentration may decrease gently toward the substrate surface even at a position away from the surface of the semiconductor substrate 10. Note that, in the semiconductor device 100 of the present example, a region in which the oxygen chemical concentration decreases toward the lower surface 23 has been ground in the manufacturing process. The decreasing portion 220 may be provided in the entire region from the depth position Zb to the depth position Zu.

The concentration of the thermal donor in each depth position varies according to the oxygen chemical concentration at each depth position. The concentration distribution of the thermal donor of the present example includes a decreasing portion 230 in which the concentration of the thermal donor decreases toward the upper surface 21 of the semiconductor substrate 10 in the region from the depth position Zb to the depth position Zu. In the decreasing portion 230, the concentration of the thermal donor decreases as the distance to the upper surface 21 is reduced. The decreasing portion 230 does not include a region in which the thermal donor concentration increases as the distance to the upper surface 21 is reduced. The decreasing portion 230 may be provided in a part of or the entire region from the depth position Zb to the depth position Zu. In the decreasing portion 230, the thermal donor concentration at the depth position Zu may decrease to be equal to or less than a half of, equal to or less than ¼ of, equal to or less than 1/10 of the thermal donor concentration at the depth position Zb, or to be 0.

The decreasing portion 230 of the present example includes a region 240 in which a logarithmic gradient αth of the concentration of the thermal donor toward the upper surface 21 side of the semiconductor substrate 10 is equal to or more than 0.5 times and equal to or less than 10 times a logarithmic gradient αox of the oxygen chemical concentration. This allows reduction in the ratio of the thermal donor relative to the doping concentration of the drift region 18 or the buffer region 20, and thus the characteristic variation of the semiconductor device 100 can be suppressed. The depth position at the lower end of the region 240 is defined as Xa, and the depth position at the upper end is defined as Xb. The center position in the depth direction of the semiconductor substrate 10 is defined as Zc. The depth position Xa may be arranged in a range from the depth position Zc to Zb. The depth position Xa may be identical to the depth position Zb. The depth position Xb may be arranged in a range from the depth position Zc to Zb or may be arranged in a range from the depth position Zc to Zu. The depth position Xb may be arranged on the lower surface 23 side relative to a region in which the oxygen chemical concentration changes steeply. The depth position Xb may be away from the upper surface 21 of the semiconductor substrate 10 by 10 μm or more, 20 μm or more, or 30 μm or more. The region 240 may have a length of 10 μm or more or 20 μm or more in the depth direction.

The oxygen chemical concentration at the depth position Xa is defined as Noxa and the thermal donor concentration at the depth position Xa is defined as Ntha. The oxygen chemical concentration at the depth position Xb is defined as Noxb and the thermal donor concentration at the depth position Xb is defined as Nthb. The logarithmic gradient αth of the concentration of the thermal donor and the logarithmic gradient αox of the oxygen chemical concentration of the region 240 are defined in the following expressions.

$$α th = \vert {log}_{10} ( Ntha ) - {log}_{10} ( Nthb ) \vert / \vert Xa - Xb \vert$$

$$α ox = \vert {log}_{10} ( Noxa ) - {log}_{10} ( Noxb ) \vert / \vert Xa - Xb \vert$$

In the region 240, the logarithmic gradient αth of the thermal donor concentration may be equal to or more than 0.8 times or equal to or more than one time the logarithmic gradient αox of the oxygen chemical concentration. In the region 240, the logarithmic gradient αth of the thermal donor concentration may be equal to or less than 7 times or equal to or less than 4 times the logarithmic gradient αox of the oxygen chemical concentration.

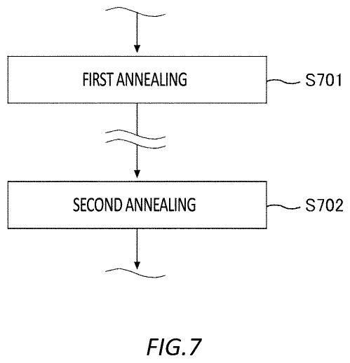

FIG. 7 is a flowchart describing an example of a manufacturing method of the semiconductor device 100. The manufacturing method includes one or more processes to anneal the semiconductor substrate 10. The manufacturing method includes processes after cutting out a semiconductor wafer from a semiconductor ingot to the completion of the semiconductor device 100. The manufacturing method in the example of FIG. 7 includes a first annealing step S701 and a second annealing step S702, although the annealing step in the manufacturing method may be one or may be three or more. In each annealing step, the semiconductor substrate 10 is heated to a temperature equal to or higher than room temperature (25° C.). In at least one annealing step, the semiconductor substrate 10 may be heated to a temperature equal to or higher than 400° C.

As described above, the concentration of the thermal donor formed in the semiconductor substrate 10 can be controlled by the thermal history relative to the semiconductor substrate 10. In the manufacturing method of the present example, the semiconductor substrate 10 is annealed so that the concentration Nth of the thermal donor is 10% or less of the concentration ID of the increased donor at the same depth position throughout the entire first range 200 shown in FIG. 5.

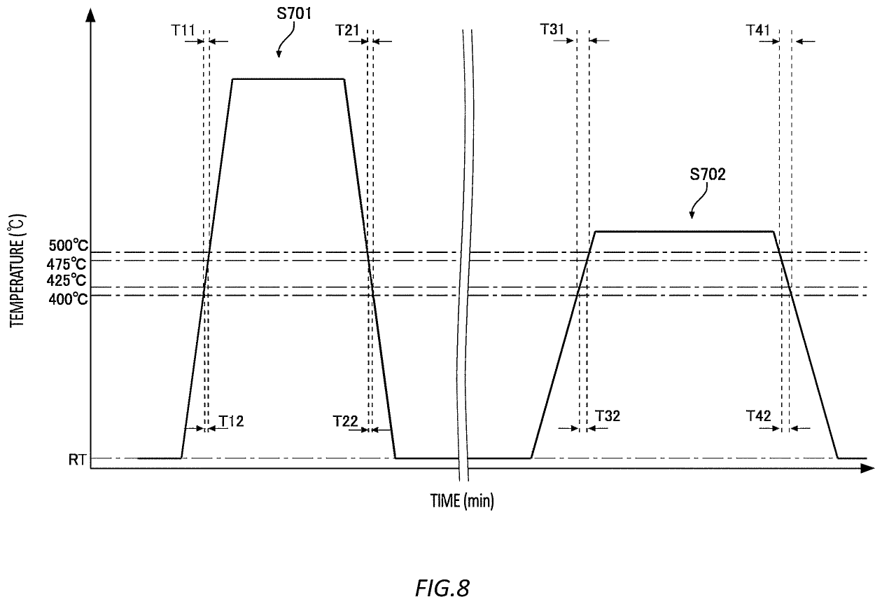

FIG. 8 illustrates an exemplary temporal variation in the temperature of the semiconductor substrate 10 in each annealing step. The horizontal axis represents time and the vertical axis represents temperatures (° C.) of the semiconductor substrate 10 in FIG. 8. In each annealing step, the semiconductor substrate 10 is heated from room temperature (RT=25° C.) to a predetermined temperature. In the example of FIG. 8, the semiconductor substrate 10 is heated to 500° C. or more in both the first annealing step S701 and the second annealing step S702.

In the semiconductor substrate 10 such as silicon, the thermal donor is likely to be formed when the temperature of the semiconductor substrate 10 is around 450° C. Thus, by controlling a time period during which the semiconductor substrate 10 passes through a predetermined first temperature zone in each annealing step, the formation of the thermal donor can be suppressed. In the example of FIG. 8, the lower limit temperature of the first temperature zone is defined as 400° C., and the upper limit temperature is defined as 500° C. In each process to anneal the semiconductor substrate 10, a time period during which the temperature of the semiconductor substrate 10 passes through the first temperature zone of 400° C. or more and 500° C. or less may be 20 minutes or less per one passage. In the example of FIG. 8, in the first annealing step S701, a time period during which the temperature of the semiconductor substrate 10 passes through the first temperature zone in the temperature-rising process is defined as T11 and a time period during which it passes through the first temperature zone in the temperature-falling process is defined as T21, and in the second annealing step S702, a time period during which it passes through the first temperature zone in the temperature-rising process is defined as T31 and a time period during which it passes through the first temperature zone in the temperature-falling process is defined as T41. Each of T11, T21, T31, and T41 may be 20 minutes or less. This can suppress the formation of the thermal donor in the semiconductor substrate 10 when it passes through the first temperature zone. Each of T11, T21, T31, and T41 may be 10 minutes or less or 5 minutes or less. Alternatively, the average time period of T11, T21, T31, and T41 may be 10 minutes or less or 5 minutes or less.

An accumulated time period of the time periods of all processes from the start to the end of the manufacturing process of the semiconductor device 100, during each of which the temperature of the semiconductor substrate 10 passes through the first temperature zone (400° C. or more and 500° C. or less) in each process to anneal the semiconductor substrate 10, may be 120 minutes or less. In the example of FIG. 8, the total of T11, T21, T31, and T41 is 120 minutes or less. This can suppress the total amount of thermal donors to be formed in the semiconductor substrate 10. The accumulated time period of the time periods during each of which the temperature of the semiconductor substrate 10 passes through the first temperature zone may be 60 minutes or less or 40 minutes or less.

The temperature zone of 425° C. or more and 475° C. or less is defined as a second temperature zone. In the second temperature zone, the thermal donor is more likely to be formed in the semiconductor substrate 10. In each process to anneal the semiconductor substrate 10, a time period during which the temperature of the semiconductor substrate 10 passes through the second temperature zone of 425° C. or more and 475° C. or less may be 10 minutes or less per one passage. In the example of FIG. 8, in the first annealing step S701, a time period during which the temperature of the semiconductor substrate 10 passes through the second temperature zone in the temperature-rising process is defined as T12 and a time period during which it passes through the second temperature zone in the temperature-falling process is defined as T22, and in the second annealing step S702, a time period during which it passes through the second temperature zone in the temperature-rising process is defined as T32 and a time period during which it passes through the second temperature zone in the temperature-falling process is defined as T42. Each of T12, T22, T32, and T42 may be 10 minutes or less. This can suppress the formation of the thermal donor in the semiconductor substrate 10 when it passes through the second temperature zone. Each of T12, T22, T32, and T42 may be 5 minutes or less or 3 minutes or less. Alternatively, the average time period of T12, T22, T32, and T42 may be 5 minutes or less or 3 minutes or less.

An accumulated time period of the time periods of all processes from the start to the end of the manufacturing process of the semiconductor device 100, during each of which the temperature of the semiconductor substrate 10 passes through the second temperature zone (425° C. or more and 475°° C. or less) in each process to anneal the semiconductor substrate 10, may be 60 minutes or less. In the example of FIG. 8, the total of T12, T22, T32, and T42 is 60 minutes or less. This can suppress the total amount of thermal donors to be formed in the semiconductor substrate 10. The accumulated time period of the time periods during each of which the temperature of the semiconductor substrate 10 passes through the second temperature zone may be 30 minutes or less or 20 minutes or less.

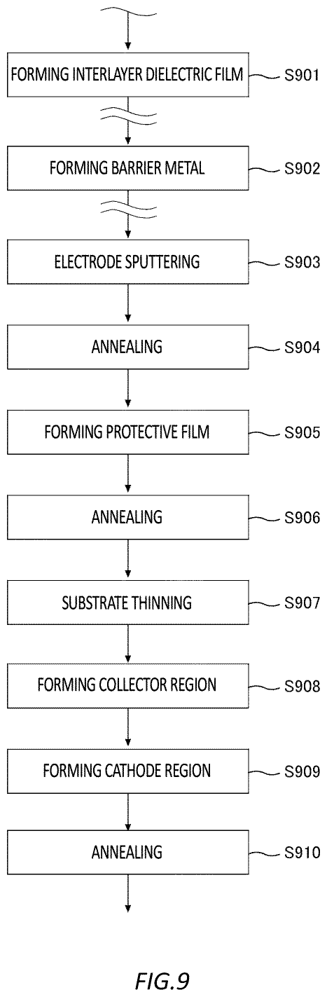

FIG. 9 is a flowchart showing a more specific example of the manufacturing method of the semiconductor device 100. In the example of FIG. 9, some processes of the manufacturing method are omitted. In the present example, an interlayer dielectric film 38 is formed on the upper surface 21 of the semiconductor substrate 10 (S901). In processes before S901, the method may include a plurality of processes to heat the semiconductor substrate 10 to a temperature higher than the room temperature (25° C.). In S901, the semiconductor substrate 10 may be heated to a temperature of 400° C. or more and 900° C. or less. The time period during which the temperature of the semiconductor substrate 10 passes through the first temperature zone and the second temperature zone, as described in FIG. 7 and FIG. 8, includes the time periods of all processes in which the temperature of the semiconductor substrate 10 passes through the first temperature zone and the second temperature zone.

After the interlayer dielectric film 38 is formed, a contact hole 54 is formed in the interlayer dielectric film 38. After the contact hole 54 is formed, barrier metal may be formed inside the contact hole 54 (S902). In S902, the semiconductor substrate 10 may be heated to a temperature of 400° C. or more and 700° C. or less. The barrier metal may include a film of at least one of titanium or titanium nitride.

After the barrier metal is formed, a metal electrode (an emitter electrode 52 in the present example) is formed above the upper surface 21 of the semiconductor substrate 10 by sputtering (S903). After the emitter electrode 52 is formed, the semiconductor substrate 10 is introduced in an annealing furnace or the like to be annealed (S904). Unless otherwise explained specifically, when heating the semiconductor substrate 10, the entire semiconductor substrate 10 is heated in the annealing furnace or the like. In S904, the semiconductor substrate 10 may be heated to a temperature less than 400° C.

After the emitter electrode 52 is formed, a protective film is formed on the emitter electrode 52 (S905). The protective film is formed of polyimide or the like, for example. After the protective film is formed, the semiconductor substrate 10 is heated to a cure temperature of the protective film (S906). In S906, the semiconductor substrate 10 may be heated to a temperature less than 400° C.

After the protective film is formed, the semiconductor substrate 10 is thinned according to a breakdown voltage that the semiconductor device 100 should have (S907). In S907, the thickness of the semiconductor substrate 10 is adjusted by grinding the lower surface 23 of the semiconductor substrate 10.

After the semiconductor substrate 10 is thinned, the collector region 22 is formed (S908) and the cathode region 82 is formed (S909) in the lower surface 23 of the semiconductor substrate 10. Any of S908 and S909 may be performed first. In S908 and S909, dopant ions are implanted in each region.

After the dopant ions are implanted in the collector region 22 and the cathode region 82, the semiconductor substrate 10 is annealed to activate the dopants (S910). In S910, the semiconductor substrate 10 may be locally heated by laser annealing or the like.

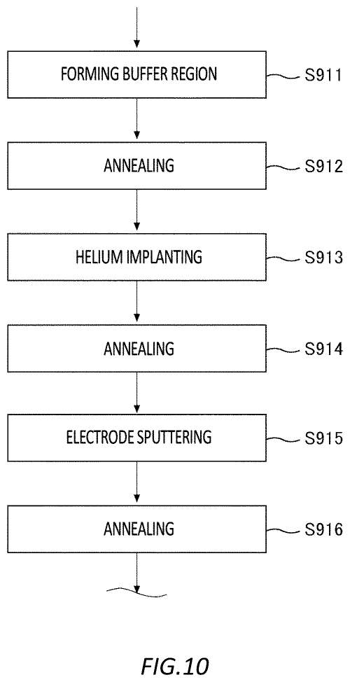

FIG. 10 is a flowchart showing processes following the processes of FIG. 9. After the collector region 22 and the cathode region 82 are formed, a buffer region 20 is formed (S911). In S911, dopant ions such as protons are implanted in the buffer region 20.

After the dopant ions are implanted in the buffer region 20, the semiconductor substrate 10 is annealed to activate the dopants (S912). In S912, the semiconductor substrate 10 may be heated to a temperature less than 400° C.

After the buffer region 20 is formed, the semiconductor substrate 10 may be irradiated with charged particles such as helium to form lifetime killer (S913). The lifetime killer is a recombination center of a lattice defect or the like and shortens the lifetime of a carrier by combining with the carrier of the semiconductor substrate 10. For example, the upper surface 21 side of the diode portion 80 may be irradiated with the charged particles such as helium. After being irradiated with the charged particles such as helium, the semiconductor substrate 10 is annealed (S914). In S914, the semiconductor substrate 10 may be heated to a temperature less than 400° C.

After the lifetime killers are formed, the collector electrode 24 is formed by sputtering (S915). After the collector electrode 24 is formed, the semiconductor substrate 10 is annealed (S916). In S916, the semiconductor substrate 10 may be heated to a temperature less than 300° C. After the collector electrode 24 is formed, the semiconductor wafer may be diced and singulated into semiconductor chips.

In the manufacturing method of the present example, the processes after the formation of the emitter electrode 52 (the processes of S905 and thereafter) are performed at less than 400° C. This can suppress the formation of the thermal donor in the semiconductor substrate 10. The processes after the formation of the emitter electrode 52 may be performed at 390° C. or less, or 380° C. or less. In the manufacturing method of the present example, the semiconductor substrate 10 is heated to a temperature of 400° C. or higher in S901 and S902. The temperature of the semiconductor substrate 10 in S901 and S902 may satisfy the conditions described in FIG. 7 and FIG. 8.

The annealing condition of the manufacturing method may be determined based on the oxygen chemical concentration of the semiconductor substrate 10 used. Variations in the thermal donor concentration when at least any of an annealing time, a temperature-rising rate, a temperature-falling rate, or an annealing temperature is changed may be measured in advance for each oxygen chemical concentration of the semiconductor substrate 10. Based on this measurement result, at least any of the annealing time, the temperature-rising rate, the temperature-falling rate, or the annealing temperature in each annealing step can be adjusted, and the concentration of the thermal donor to be formed in the semiconductor substrate 10 can be controlled.

While the present invention has been described with the embodiments, the technical scope of the present invention is not limited to the above-described embodiments. It is apparent to persons skilled in the art that various alterations and improvements can be added to the above-described embodiments. It is also apparent from the scope of the claims that the embodiments added with such alterations or improvements can be included in the technical scope of the present invention.

The operations, procedures, steps, stages, or the like of each process performed by a device, system, program, and method shown in the claims, embodiments, or diagrams can be realized in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A semiconductor device provided with a semiconductor substrate that has an upper surface and a lower surface, includes a bulk donor and a thermal donor, and has an oxygen chemical concentration of 1×10¹⁶ atoms/cm³ or more, the semiconductor device comprising:
a drift region of a first conductivity type that is provided on the semiconductor substrate and includes the bulk donor and the thermal donor;
a buffer region of a first conductivity type that is provided between the drift region and the lower surface of the semiconductor substrate, includes the bulk donor and an increased donor, and has a doping concentration higher than that of the drift region, wherein
the buffer region includes one or more doping concentration peaks in a depth direction of the semiconductor substrate,
the one or more doping concentration peaks include a deepest peak that is arranged farthest away from the lower surface of the semiconductor substrate,
the increased donor includes the thermal donor, and
a concentration of the thermal donor is 10% or less of a concentration of the increased donor at a same depth position throughout an entire first range from a lower end of the buffer region to the deepest peak.

2. The semiconductor device according to claim 1, wherein
the increased donor includes a CiOi-H donor.

3. The semiconductor device according to claim 1, wherein
a concentration of the thermal donor is 0.1% or more of a concentration of the increased donor at a same depth position throughout the entire first range.

4. The semiconductor device according to claim 1, wherein
an oxygen chemical concentration of the semiconductor substrate is 1×10¹⁷ atoms/cm³ or more and 5×10¹⁷ atoms/cm³ or less.

5. The semiconductor device according to claim 1, wherein
a concentration of the thermal donor in the drift region is equal to or less than 0.0001 times the oxygen chemical concentration.

6. The semiconductor device according to claim 1, wherein
a doping concentration of the drift region is equal to or less than 1.5 times a concentration of the bulk donor.

7. The semiconductor device according to claim 1, wherein
a concentration of the thermal donor is equal to or less than 0.1 times a doping concentration at a local maximum position of the deepest peak.

8. The semiconductor device according to claim 1, wherein
the buffer region includes a maximum peak, among the doping concentration peaks other than the deepest peak, at which a doping concentration is maximum, and
a concentration of the thermal donor is equal to or less than 0.01 times a doping concentration at a local maximum position of the maximum peak.

9. The semiconductor device according to claim 1, wherein
the buffer region includes a shallowest peak that is closest to the lower surface of the semiconductor substrate, and
a concentration of the thermal donor is equal to or less than 0.001 times a doping concentration at a local maximum position of the shallowest peak.

10. The semiconductor device according to claim 1, wherein
in a region that is on a side of the upper surface of the semiconductor substrate relative to the buffer region, a concentration distribution of the thermal donor includes a decreasing portion in which a concentration of the thermal donor decreases toward the upper surface of the semiconductor substrate.

11. The semiconductor device according to claim 10, wherein
the decreasing portion includes a region in which a logarithmic gradient of a concentration of the thermal donor toward the side of the upper surface of the semiconductor substrate is equal to or more than 0.5 times and equal to or less than 10 times a logarithmic gradient of the oxygen chemical concentration.

12. A manufacturing method of a semiconductor device, using a semiconductor substrate that has an upper surface and a lower surface, includes a bulk donor, and has an oxygen chemical concentration of 1×10¹⁶ atoms/cm³ or more, wherein the semiconductor device comprises:
a drift region of a first conductivity type that is provided on the semiconductor substrate and includes the bulk donor and a thermal donor;
a buffer region of a first conductivity type that is provided between the drift region and the lower surface of the semiconductor substrate, includes the bulk donor and an increased donor, and has a doping concentration higher than that of the drift region, wherein
the buffer region includes one or more doping concentration peaks in a depth direction of the semiconductor substrate,
the one or more doping concentration peaks includes a deepest peak that is arranged farthest away from the lower surface of the semiconductor substrate,
the increased donor includes the thermal donor, and
the semiconductor substrate is annealed so that a concentration of the thermal donor is 10% or less of a concentration of the increased donor at a same depth position throughout an entire first range from a lower end of the buffer region to the deepest peak.

13. The manufacturing method of a semiconductor device according to claim 12, wherein
in each process to anneal the semiconductor substrate, a time period during which a temperature of the semiconductor substrate passes through a temperature zone from 400° C. or more and 500° C. or less is 20 minutes or less per one passage.

14. The manufacturing method of a semiconductor device according to claim 12, wherein
in each process to anneal the semiconductor substrate, a time period during which a temperature of the semiconductor substrate passes through a temperature zone from 425° C. or more and 475° C. or less is 10 minutes or less per one passage.

15. The manufacturing method of a semiconductor device according to claim 12, wherein
an accumulated time period of time periods during each of which a temperature of the semiconductor substrate passes through a temperature zone from 400° C. or more and 500° C. or less in each process to anneal the semiconductor substrate is 120 minutes or less.

16. The manufacturing method of a semiconductor device according to claim 12, wherein
an accumulated time period of time periods during each of which a temperature of the semiconductor substrate passes through a temperature zone from 425° C. or more and 475° C. or less in each process to anneal the semiconductor substrate is 60 minutes or less.

17. The manufacturing method of a semiconductor device according to claim 12, wherein
a metal electrode is formed above the upper surface of the semiconductor substrate, and
a process after the metal electrode is formed is performed at less than 400° C.

18. The semiconductor device according to claim 2, wherein
a concentration of the thermal donor is equal to or less than 0.1 times a doping concentration at a local maximum position of the deepest peak.

19. The semiconductor device according to claim 3, wherein
a concentration of the thermal donor is equal to or less than 0.1 times a doping concentration at a local maximum position of the deepest peak.

20. The semiconductor device according to claim 4, wherein
a concentration of the thermal donor is equal to or less than 0.1 times a doping concentration at a local maximum position of the deepest peak.
